(19) United States
(12) Patent Application Publication
(10) Pub. No.: US 2026/0150364 A1
(43) Pub. Date: May 28, 2026

(54) SEMICONDUCTOR DEVICE AND FORMATION METHOD THEREOF

(71) Applicant: Taiwan Semiconductor Manufacturing Co., Ltd., Hsinchu (TW)

(72) Inventors: Szu-Hua Chen, Tainan City (TW); Jin-Hao Jhang, Chubei City (TW); Chu-Hsuan Sha, Taipei City (TW); Wei-Yen Woon, Taoyuan City (TW); Szuya Liao, Zhubei (TW)

(21) Appl. No.: 19/072,406

(22) Filed: Mar. 6, 2025

Related U.S. Application Data
(60) Provisional application No. 63/723,693, filed on Nov. 22, 2024.

(51) Int. Cl. H10D 64/01; H10D 84/01

(52) U.S. Cl. CPC H10D 64/017; H10D 84/0142

(57) ABSTRACT

A method includes forming a lower source/drain region, forming a upper source/drain region over the lower source/drain region, forming a contact etch stop layer over the upper source/drain region, and forming an inter-layer dielectric over the contact etch stop layer. The method further includes recessing the inter-layer dielectric to form a first recess, forming a first hard mask in the first recess, and forming a second hard mask in the first recess and over the first hard mask. A dummy gate stack aside of the second hard mask is removed to form a second recess, and a sacrificial material is deposited into the second recess. A chemical mechanical polish (CMP) process is performed on the sacrificial material, wherein remaining portion of the sacrificial material is left in the second recess to form a sacrificial region. Tn the CMP process, the second hard mask acts as a CMP stop layer.

### PRIORITY CLAIM AND CROSS-REFERENCE

This application claims the benefit of the following provisionally filed U.S. Patent application: Application No. 63/723,693, filed on Nov. 22, 2024, and entitled “SEMICONDUCTOR DEVICE AND FORMATION METHOD THEREOF;” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2 through 23 are views of intermediate stages in the manufacturing of CFETs in accordance with some embodiments.

FIG. 24 illustrates a process flow for forming a CFET in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Complementary Field-Effect Transistor (CFET) and the method of forming the same are provided. In accordance with some embodiments, a hard mask including an upper hard mask layer and a lower hard mask layer are formed. The upper hard mask layer and the lower hard mask layer have different functions in the formation of the CFET structure. For example, the upper hard mask layer may be used for the selective dipole doping to the high-k dielectric layer of one of the upper FET and the lower FET. The upper hard mask layer has a high selectivity to a sacrificial layer that is used to protect the high-k dielectric layer of the lower FET. The lower hard mask layer may have a high selectivity in the etching back of metal gates.

It is appreciated that while Gate-All-Around (GAA) transistors (such as nanostructure-FETs) are discussed as examples for forming the CFETs, the concept of the present disclosure can also be applied to the formation of other types of transistors such as planar transistors, Fin Field-Effect Transistors (FinFETs), or the like. Throughout the description, the terms “FET” and “transistor” are used interchangeably.

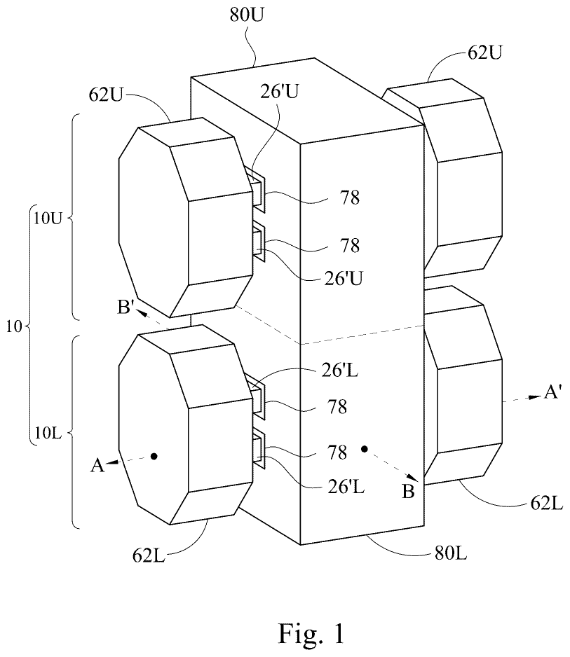

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Subsequent figures may refer to these reference cross-sections for clarity.

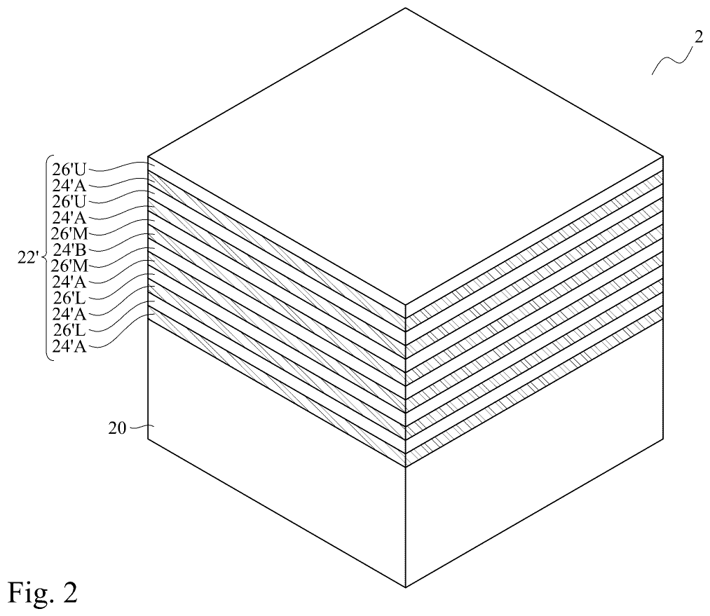

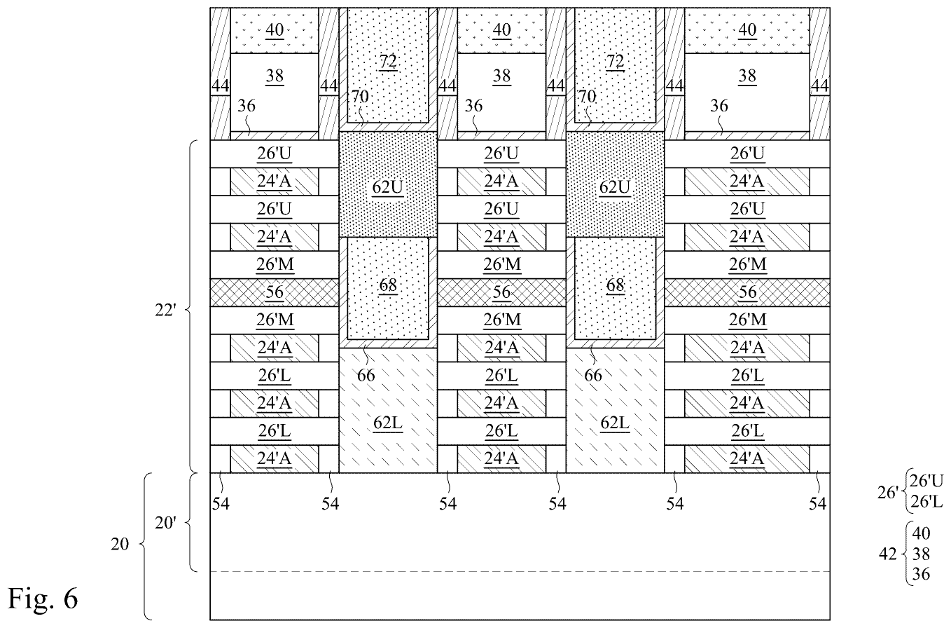

FIGS. 2 through 23 illustrate the cross-sectional views of intermediate stages in the formation of CFETs (as schematically represented in FIG. 1) in accordance with some embodiments. The corresponding processes are also reflected schematically in the process flow shown in FIG. 37. In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the cross-sectional views along a similar cross-section as the vertical reference cross-section B-B′ in FIG. 1.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

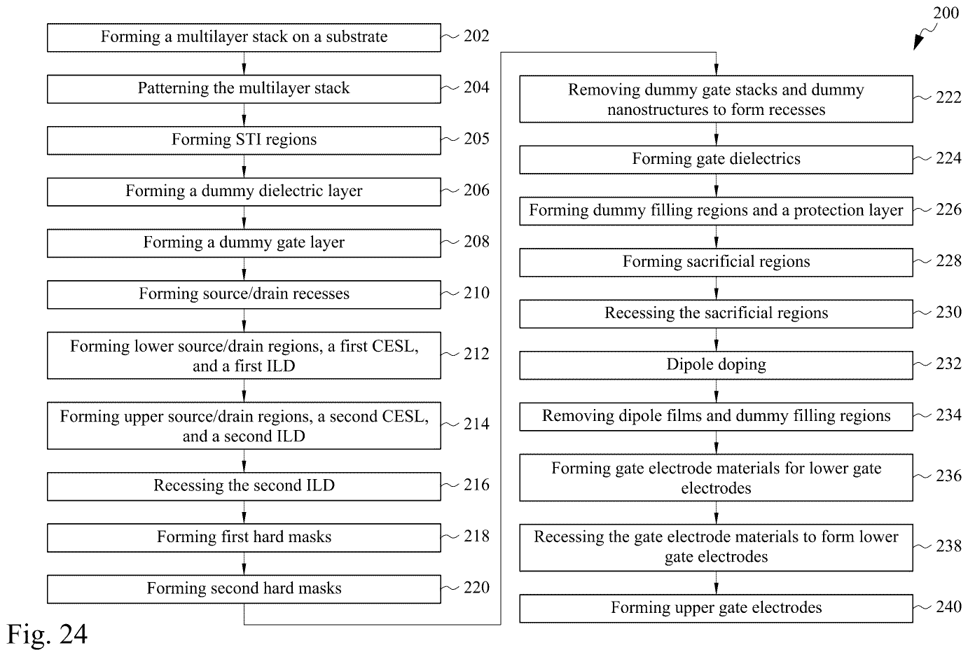

A multi-layer stack 22 is formed over the substrate 20. The respective process is illustrated as process 202 in the process flow 200 as shown in FIG. 24. The multi-layer stack 22 includes alternating dummy semiconductor layers 24 (including dummy semiconductor layers 24A and 24B) and semiconductor layers 26 (including lower semiconductor layers 26L and upper semiconductor layers 26U). Lower semiconductor layers 26L and upper semiconductor layers 26U are for forming a lower FET and an upper FET, respectively.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

In the illustrated example, the multi-layer stack 22 includes six of the dummy semiconductor layers 24 and six of the semiconductor layers 26. It should be appreciated that the multi-layer stack 22 may include any number of the dummy semiconductor layers 24 and the semiconductor layers 26. Each layer of the multi-layer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

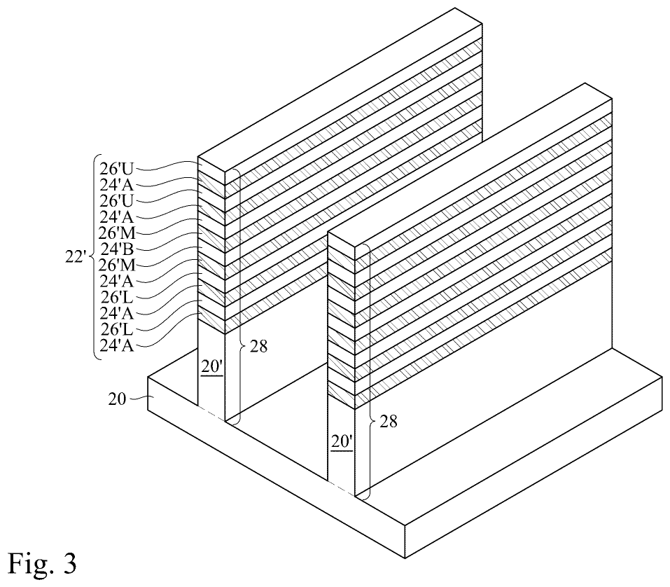

In FIG. 3, multi-layer stack 22 and substrate 20 are patterned to form semiconductor strips 28. The respective process is illustrated as process 204 in the process flow 200 as shown in FIG. 24. Each of semiconductor strips 28 includes semiconductor strip 20′ (the portions of the original substrate 20) and multi-layer stack 22′, which is the remaining portion of multi-layer stack 22. The remaining portions 22′ of multi-layers stack 22 are referred to as nanostructures hereinafter, which are referred to using the corresponding reference number followed by a “′” sign. Accordingly, multi-layer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

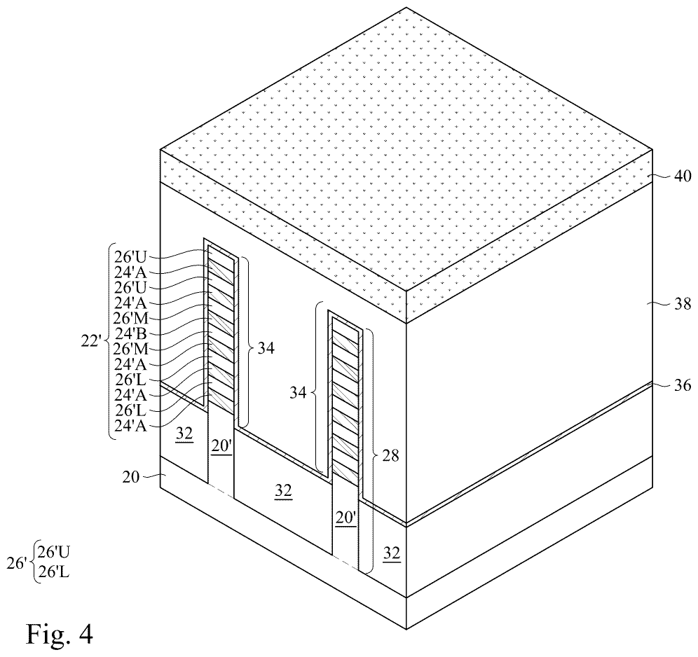

In FIG. 4, isolation regions 32 are formed over the substrate 20 and between adjacent semiconductor strips 28. The respective process is illustrated as process 205 in the process flow 200 as shown in FIG. 24. Isolation regions 32 may include a dielectric liner and a dielectric material over the dielectric liner. Isolation regions 32 are then recessed. Some upper portions of semiconductor strips 28 (including multi-layer stacks 22′) protrude higher than the remaining isolation regions 32 to form protruding fins 34.

Dummy dielectric layer 36 is then formed on the protruding fins 34. The respective process is illustrated as process 206 in the process flow 200 as shown in FIG. 24. Dummy dielectric layer 36 may be formed of or comprise, for example, silicon oxide, silicon nitride, a combination thereof, or the like, and may be deposited or thermally grown according to acceptable techniques.

A dummy gate layer 38 is formed over the dummy dielectric layer 36. The respective process is illustrated as process 208 in the process flow 200 as shown in FIG. 24. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

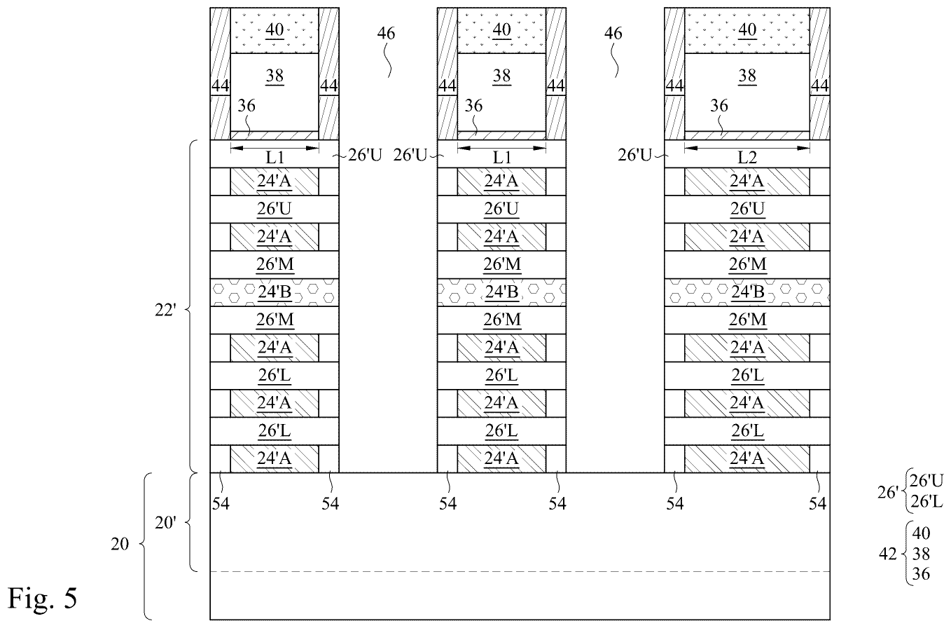

Next, the mask layer 40 may be patterned through photolithography and etching processes to form a mask, which is then used to etch and pattern dummy gate layer 38, and possibly dummy dielectric layer 36. A resulting structure is shown in FIG. 5. The remaining portions of mask layer 40, dummy gate layer 38, and dummy dielectric layer 36 form dummy gate stacks 42.

In FIG. 5, gate spacers 44 are formed over the multi-layer stacks 22′ and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

FIG. 5 illustrates an example in which the FETs have different channel lengths. For example, some of the FETs to be formed may have channel lengths L1, and other FETs to be formed may have channel length L2 greater than channel length L1. The ratio L2/L1 may be in the range between about 1.2 and about 5.

Source/drain recesses 46 are then formed in semiconductor strips 28. The respective process is illustrated as process 210 in the process flow 200 as shown in FIG. 24. The source/drain recesses 46 are formed through etching, and may extend through the multi-layer stacks 22′ and into the semiconductor strips 20′. The bottom surfaces of the source/drain recesses 46 may be at a level above, below, or level with the top surfaces of the isolation regions 32 (FIG. 4). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

Dielectric isolation layers 56 are then formed to replace the dummy nanostructures 24′B. Dummy nanostructures 24′A are also laterally recessed, and a dielectric material is filled into the respective recesses to form inner spacers 54, which are dielectric spacers.

Next, lower epitaxial source/drain regions 62L are formed in the lower portions of the source/drain recesses 46 (FIG. 5). The respective process is illustrated as process 212 in the process flow 200 as shown in FIG. 24. The lower epitaxial source/drain regions 62L are in contact with the lower semiconductor nanostructures 26′L and are not in contact with the upper semiconductor nanostructures 26′U. Inner spacers 54 electrically insulate the lower epitaxial source/drain regions 62L from the dummy nanostructures 24′A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants

A first contact etch stop layer (CESL) 66 and a first ILD 68 are formed. The respective process is also illustrated as process 212 in the process flow 200 as shown in FIG. 24. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

Next, upper epitaxial source/drain regions 62U are formed in the upper portions of the source/drain recesses 46. The respective process is illustrated as process 214 in the process flow 200 as shown in FIG. 24. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant.

Next, a second CESL 70 and a second ILD 72 are formed. The respective process is also illustrated as process 214 in the process flow 200 as shown in FIG. 24. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

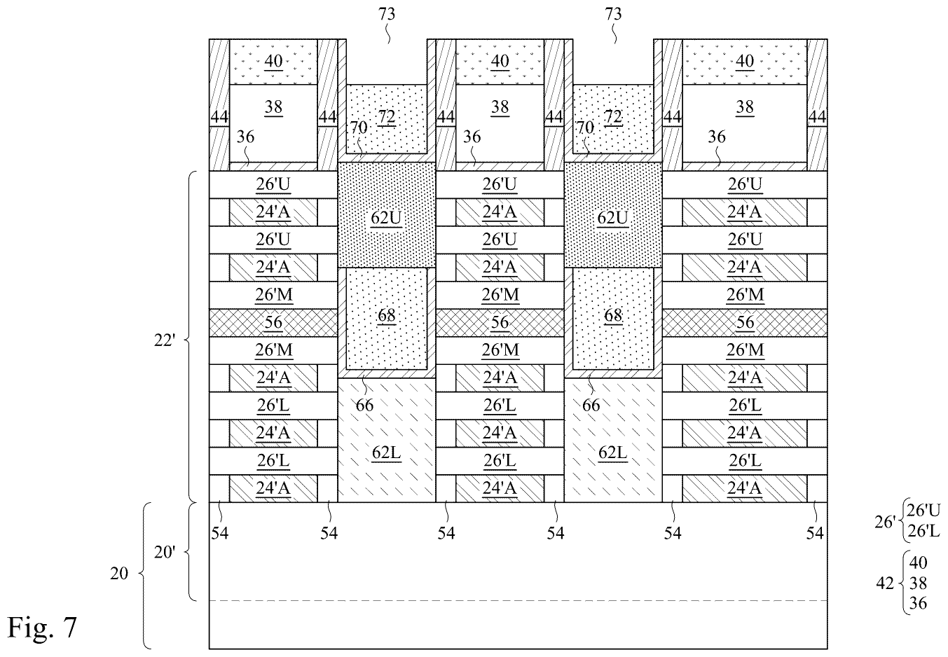

Referring to FIG. 7, ILD 72 is recessed through etching to form recesses 73. The respective process is illustrated as process 216 in the process flow 200 as shown in FIG. 24. In accordance with some embodiments, CESL 70 is not recessed, and the vertical portions of CESL 70 have their sidewalls exposed to recesses 73. In accordance with alternative embodiments, CESL 70 is also recessed along with ILD 72, and hence the sidewalls of gate spacers 44 may be exposed to recesses 73.

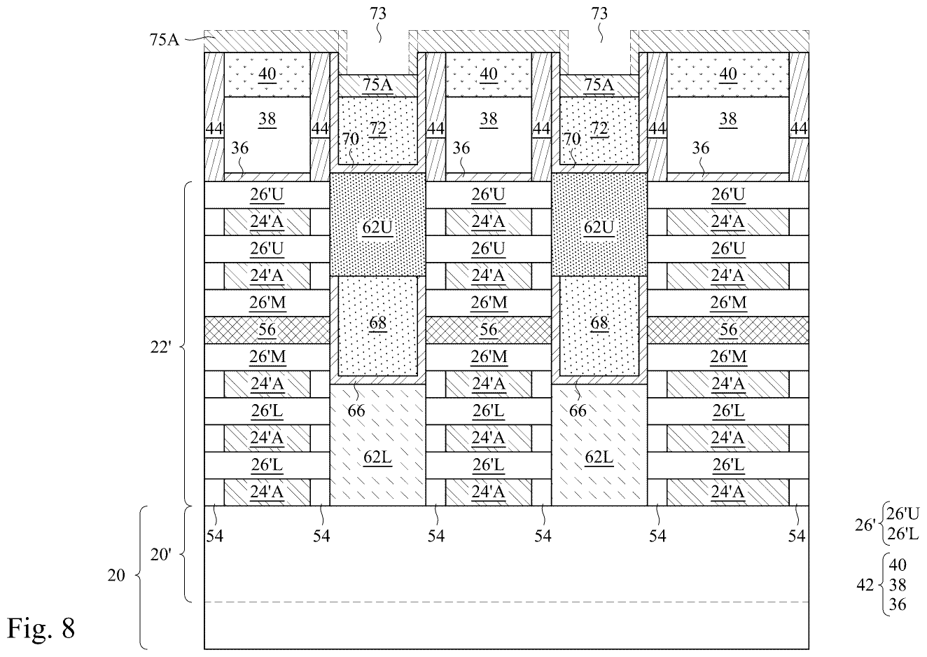

FIG. 8 illustrates the formation of (first/lower) hard masks 75A, which may comprise a deposition process. The respective process is illustrated as process 218 in the process flow 200 as shown in FIG. 24. In accordance with some embodiments, hard masks 75 comprise SiN, SiON, or the like. The deposition method may include Plasma enhanced ALD (PEALD), PECVD, or the like. In the deposition process, a precursor gas (such as silane, di-silane, dichlorosilane (DCS), or the like) is conducted into a processing chamber, in which the respective wafer 2 is placed.

The precursor gas is ionized to form ionized precursor molecules. A bias voltage is applied, so that the ionized precursor molecules are attracted to wafer 2, so as to provide anisotropic coverage of wafer 2 with precursor gas molecules. A reactant gas (such as ammonia (NH₃)) is introduced into the processing chamber. A plasma is generated to cause the reactant gas to react with the ionized precursor molecules that have been anisotropically deposited onto wafer 2 to form hard masks 75A. Hard masks 75A are thus formed as bottom-up films.

As a result of the bottom-up deposition, hard masks 75A may or may not include sidewall portions on the sidewalls of CESL 70. The sidewall portions of hard masks 75A (if formed) may be much thinner than horizontal portions.

In accordance with alternative embodiments, hard mask 75A may also be formed using other methods, which may include a conformal deposition process, followed by a CMP process and an etch-back process. Accordingly, the sidewall portions of hard masks 75A and the portions of hard masks 75A over gate spacers 44 and dummy gate stacks 42 are illustrated as being dashed to indicate that these portions may or may not exist. These portions are not shown in subsequent figures.

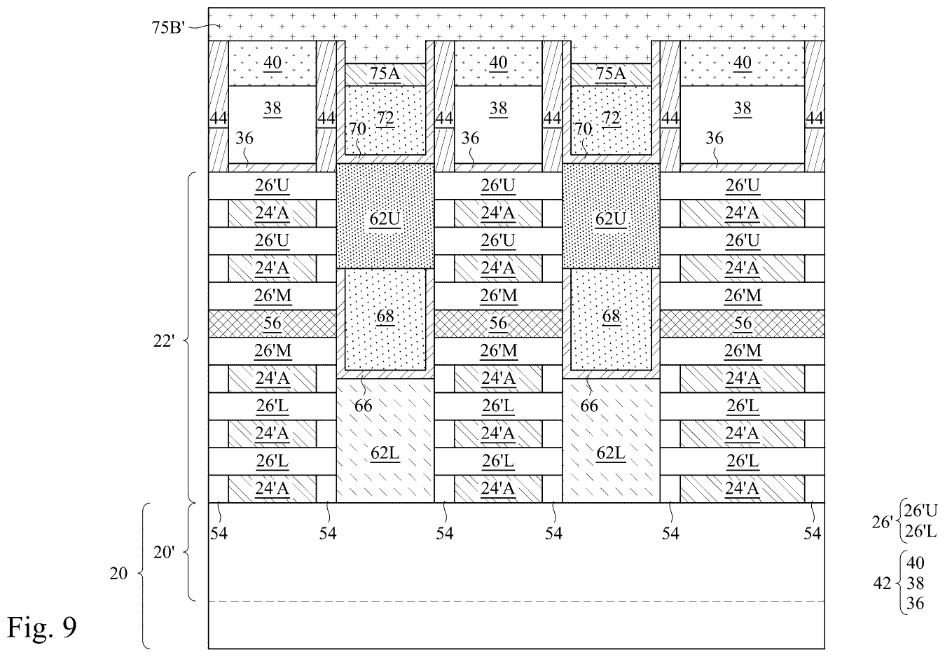

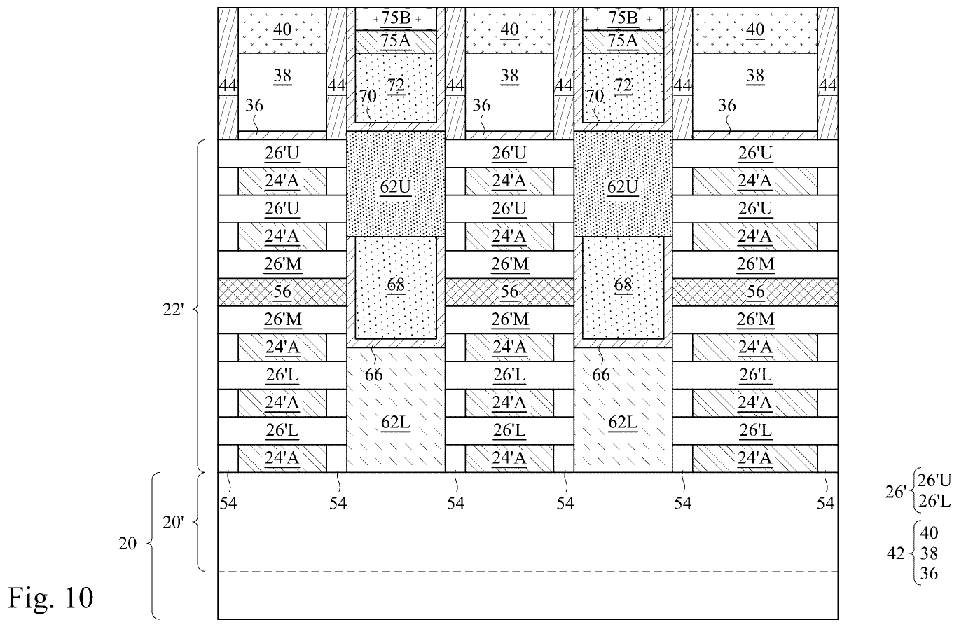

FIGS. 9 and 10 illustrate the formation of (second/upper) hard masks 75B, which comprise a material different from the material of hard masks 75A. Hard masks 75A and 75B are collectively referred to as dual-layer (double-layer) hard masks. The respective process is illustrated as process 220 in the process flow 200 as shown in FIG. 24.

In accordance with some embodiments, as shown in FIG. 9, hard mask layer 75B′ is deposited. Hard mask layer 75B′ may comprise a material different from the material of hard masks 75A. For example, hard mask layer 75B′ may comprise SiCN, SiOCN, SiC, or the like. The formation of hard mask layer 75B′ comprises a deposition process, which may comprise a conformal or a non-conformal deposition process such as ALD, CVD, PECVD, PEALD, or the like.

In a subsequent process, as shown in FIG. 10, a planarization process such as a CMP process or a mechanical polishing process is performed to remove the excess portions of hard mask layer 75B′ over gate spacers 44. The remaining portions of hard mask layer 75B′ are referred to as hard masks 75B hereinafter.

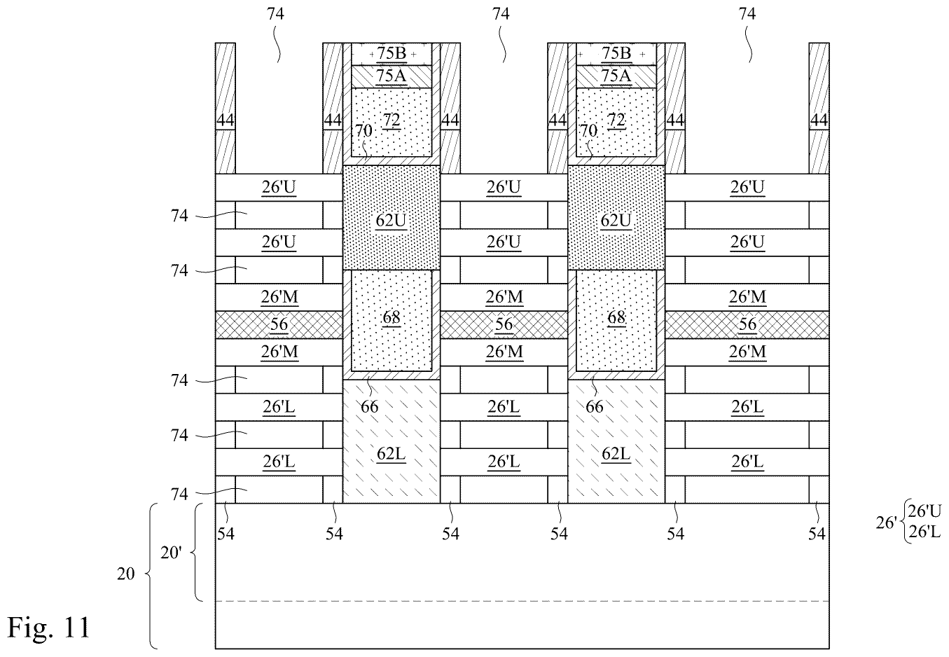

Referring to FIG. 11, the dummy gate stacks 42 and dummy nanostructures 24′A are removed in one or more etching processes, so that recesses 74 are formed. The respective process is illustrated as process 222 in the process flow 200 as shown in FIG. 24. Each of recesses 74 exposes and/or overlies portions of multi-layer stacks 22′ (FIG. 10).

The remaining portions of the dummy nanostructures 24′A (FIG. 10) are then removed through etching, so that recesses 74 extend between the semiconductor nanostructures 26′. In the etching process, the dummy nanostructures 24′A is etched at a faster rate than the semiconductor nanostructures 26′, the dielectric isolation layers 56, and the inner spacers 54. The etching may be isotropic. For example, when the dummy nanostructures 24′A are formed of silicon-germanium, and the semiconductor nanostructures 26′ are formed of silicon, the etch process may include a wet etch process using tetramethylammonium hydroxide (TMAH), ammonium hydroxide (NH₄OH), or the like.

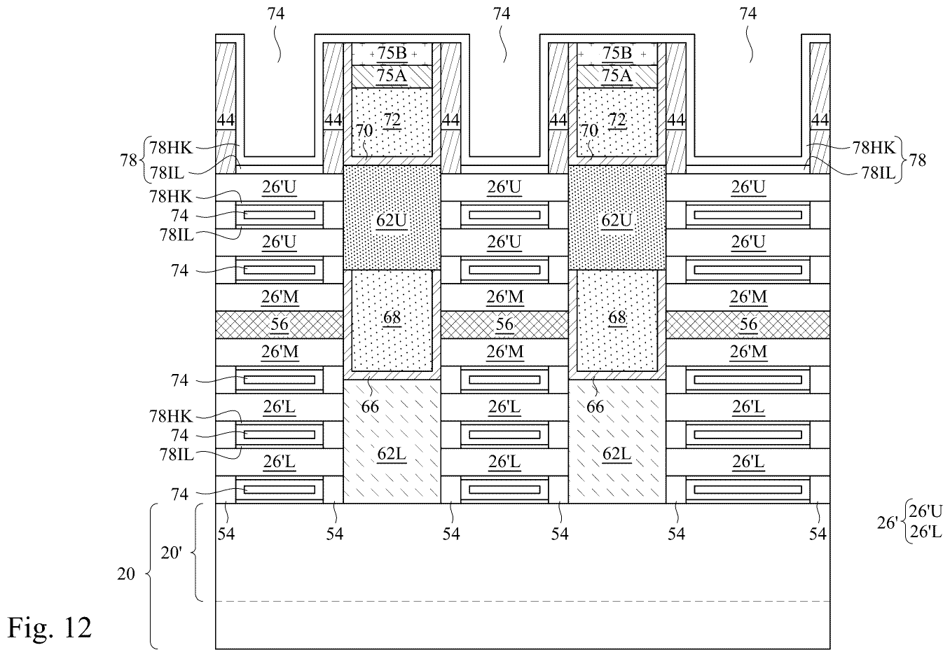

In FIG. 12, gate dielectrics 78 are formed. The respective process is illustrated as process 224 in the process flow 200 as shown in FIG. 24. The gate dielectrics 78 are formed on the exposed surfaces of the exposed features including the semiconductor nanostructures 26′ and the gate spacers 44. The gate dielectrics 78 wrap around all (e.g., four) sides of the semiconductor nanostructures 26′.

Each of the gate dielectrics 78 may include an interfacial layer 78IL, which may include an oxide such as silicon oxide. The interfacial layer 78IL may be formed through a thermal oxidation process and/or a deposition process. The gate dielectrics 78 may also include high-k dielectric layers 78HK, which have a high dielectric constant (high-k) value greater than, for example, about 7.0, about 21, or higher. High-k dielectric layers 78HK may be formed of or comprise a metal oxide or a silicate of a metal selected from hafnium, zirconium, barium, titanium, lead, and combinations thereof.

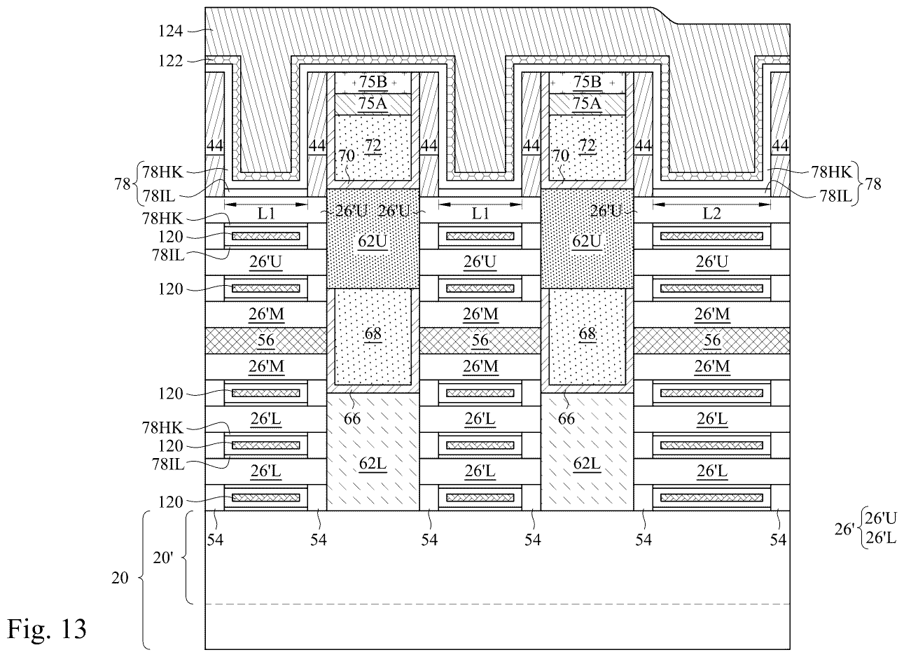

Referring to FIG. 13, (dummy) filling regions 120 are formed to fill the portions of recesses 74 between semiconductor nanostructures 26′. The respective process is illustrated as process 226 in the process flow 200 as shown in FIG. 24. The formation process may include a deposition process followed by an etching process. Since the spaces between semiconductor nanostructures 26′ are small, by controlling the etching time, filling regions 120 are left between semiconductor nanostructures 26′, while the portions of the deposited material over the top semiconductor nanostructure 26′ are removed.

Filling regions 120 may comprise SiN, SiO, aluminum oxide, aluminum nitride, titanium nitride, or the like in accordance with some embodiments. In accordance with alternative embodiments, filling regions 120 may comprise a dipole doping material, which when doped into the high-k dielectric layers 78HK of the lower FET, may reduce the threshold voltages of the lower FET. For example, when the lower FETs are PFETs, the filling regions 120 may comprise a p-type dopant such as such as Al, Ga, Zn, Ti, Ta, or the like, or combinations thereof, and may be the oxide and/or nitride of the p-type dopant.

After the formation of filling regions 120, protection layer 122 is deposited. The respective process is also illustrated as process 226 in the process flow 200 as shown in FIG. 24. In accordance with some embodiments, protection layer 122 comprises TiN, TaN, BN, or the like. Protection layer 122 is deposited into the portions of the recesses 74 left by the removed dummy gate stacks 42, and may include some portions outside of recesses 74.

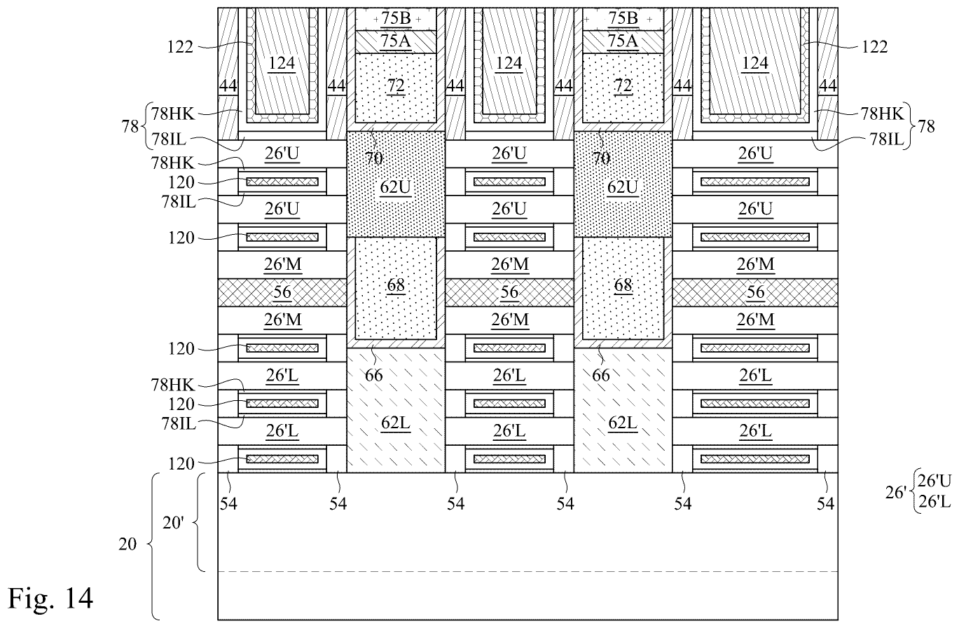

FIGS. 13 and 14 also illustrate the formation of sacrificial regions 124. The respective process is illustrated as process 228 in the process flow 200 as shown in FIG. 24. As shown in FIG. 13, a deposition process is performed to fill the remaining portions of recesses 74 with a sacrificial material, which is also referred to as sacrificial material 124. In accordance with some embodiments, sacrificial material 124 comprises SiOC, while other materials such as SiO may be used. Due to the difference in channel lengths L1 and L2, the top surfaces of the portions of sacrificial material 124 directly over the longer channel regions may be lower than the top surfaces of the portions of sacrificial regions 124 directly over the shorter channel regions.

It is appreciated that in the illustrated plane, while the bottom surfaces of sacrificial regions 124 are higher than the top one of the semiconductor nanostructures 26′U, in other planes, as can be realized from the structure in FIG. 4, sacrificial regions 124 may extend to levels lower than dielectric isolation layers 56. This is because the sacrificial regions 124 fill the spaces left by the removed dummy gate stacks 42 as shown in FIG. 4.

In accordance with alternative embodiments, the filling regions 120 are not formed, and protection layer 122 and sacrificial regions 124 may also fill the portions of recesses between semiconductor nanostructures 26′.

A planarization process such as a CMP process or a mechanical polish process is then performed to remove excess portions of the sacrificial material 124 and to form sacrificial regions 124. The resulting structure is shown in FIG. 14. During the planarization process, hard masks 75B are used as the CMP stop layers (also referred to as polish stop layers). In accordance with some embodiments, hard masks 75B would have a higher CMP rate (the reduction in thickness per unit CMP time) than hard masks 75A if hard masks 75A are exposed to the respective slurry used for the CMP process. Accordingly, by forming hard masks 75B that have a different material from the material of hard masks 75A, hard masks 75B have a lower CMP rate, and may act as an effect CMP stop layer. As a comparison, the hard masks 75A have a higher CMP rate than hard mask 75B, and if hard masks 75B are not formed, the hard masks 75A may be fully removed during the CMP process, and ILD 72 will be exposed during the CMP for forming sacrificial regions 124, causing problems in subsequent processes.

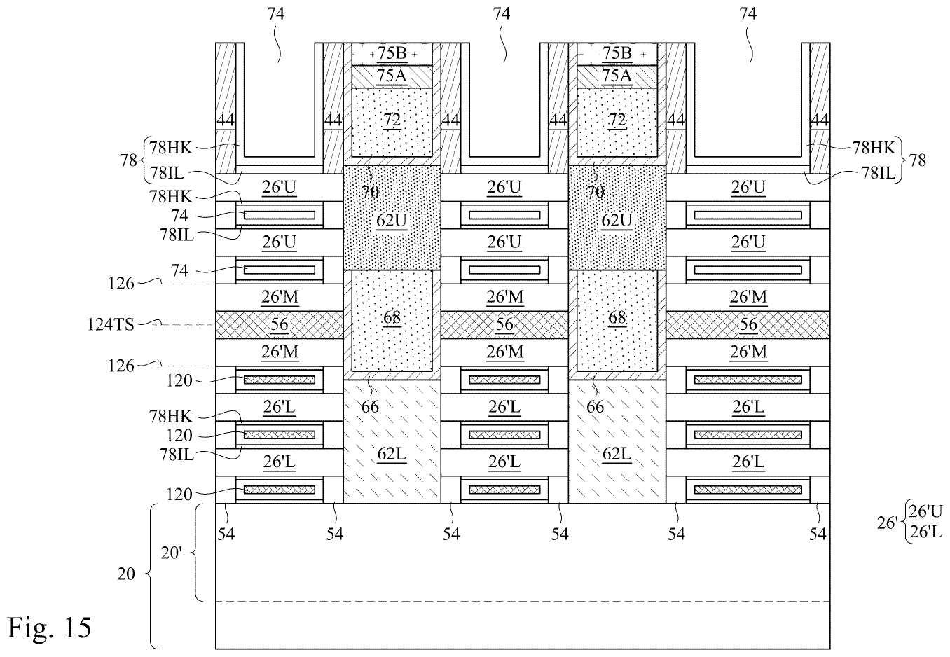

Referring to FIG. 15, in subsequent processes, sacrificial regions 124 are etched back (recessed) to reveal protection layer 122 and to regenerated recesses 74. The respective process is illustrated as process 230 in the process flow 200 as shown in FIG. 24. Some remaining portions of sacrificial regions 124 will remain in the planes that are not illustrated. The top surfaces of the remaining portions of sacrificial regions 124 will be at any level between the two illustrated dashed lines 126. Recesses 74 are thus regenerated. An example top surface of the recessed sacrificial regions 124 is illustrated as top surface 124TS. Accordingly, the portions of filling regions 120 and protection layer 122 lower than top surface 124TS are protected by the remaining portions of sacrificial regions 124.

Due to the etch back of sacrificial regions 124, some parts of protection layer 122 are also revealed again in the planes that are not illustrated. The exposed parts of protection layer 122 are then etched. The sidewalls of the portions of filling regions 120 above top surface 124TS are accordingly exposed (in the planes that is not illustrated). Filling regions 120 are then removed, and the recesses 74 further extend into the spaces between semiconductor nanostructures 26′U. As a result, the high-k dielectric layers 78HK that are higher than top surface 124TS are exposed.

The etching of filling regions 120 is controlled, so that the filling regions 120 between semiconductor nanostructures 26′L remain unremoved. Accordingly, the high-k dielectric layers 78HK that are lower than dielectric isolation layers 56 are not exposed.

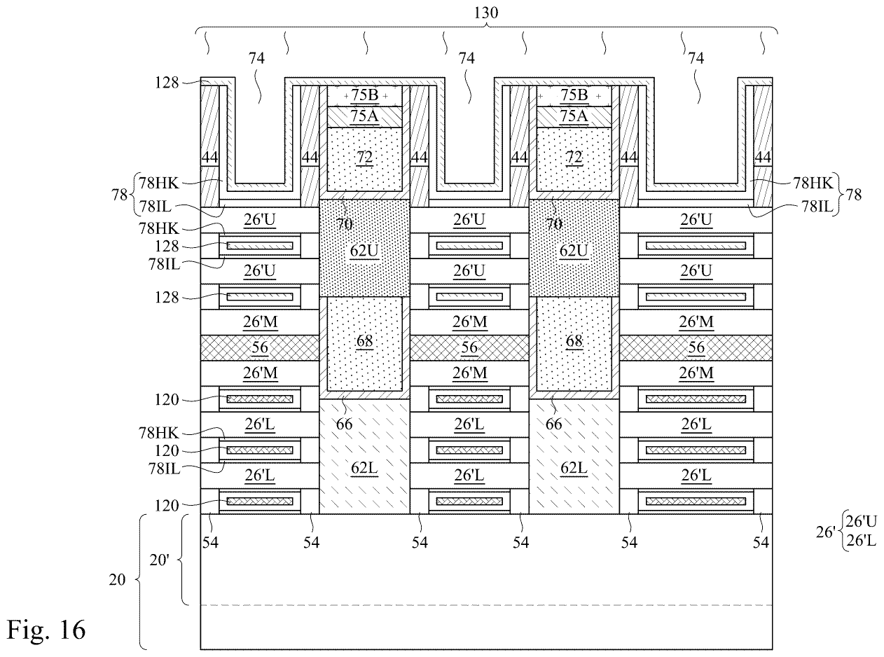

Referring to FIG. 16, a dipole doping process is performed. The respective process is illustrated as process 232 in the process flow 200 as shown in FIG. 24. Dipole film 128 is first deposited on the gate dielectrics 78 on semiconductor nanostructures 26′U. Dipole film 128 may comprise a dipole dopant that when incorporated into the gate dielectrics of the upper FET, may reduce the threshold voltages of the upper FETs. For example, when the upper FETs are NFETs, the dipole film 128 may comprise an oxide(s), a nitride(s), and/or a carbide(s) of an n-type dipole dopant(s) such as La, Sr, Y, Er, Sc, Mg, or the like, or combinations thereof.

FIG. 16 further illustrates the annealing process 130 to drive the dipole dopants in the dipole film 128 into the gate dielectrics 78 of the upper FETs through diffusion. If filling regions 120 comprises dipole dopants, the dipole dopants are also driven into the gate dielectrics 78 of the upper FETs.

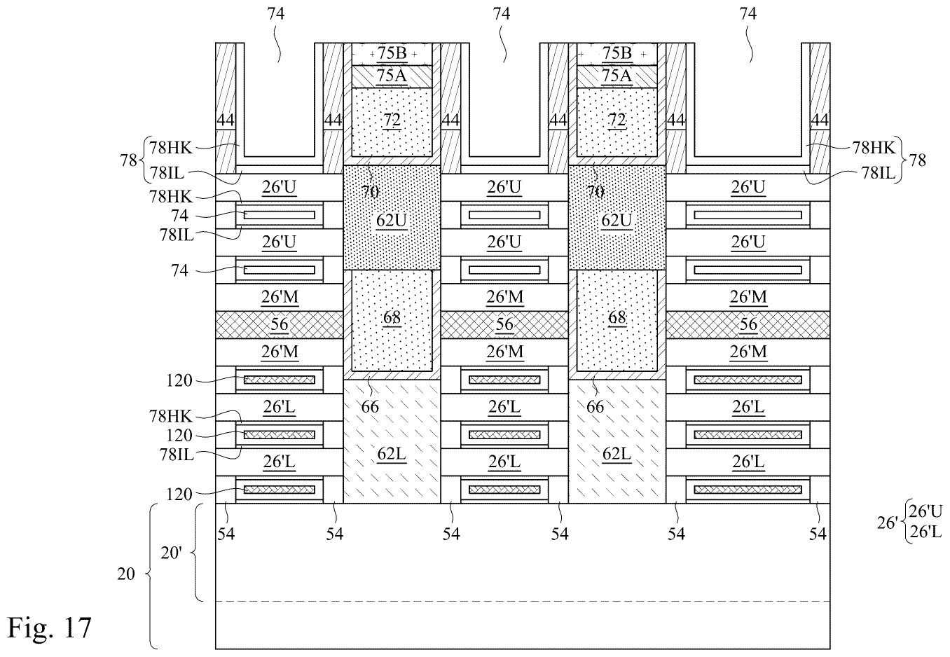

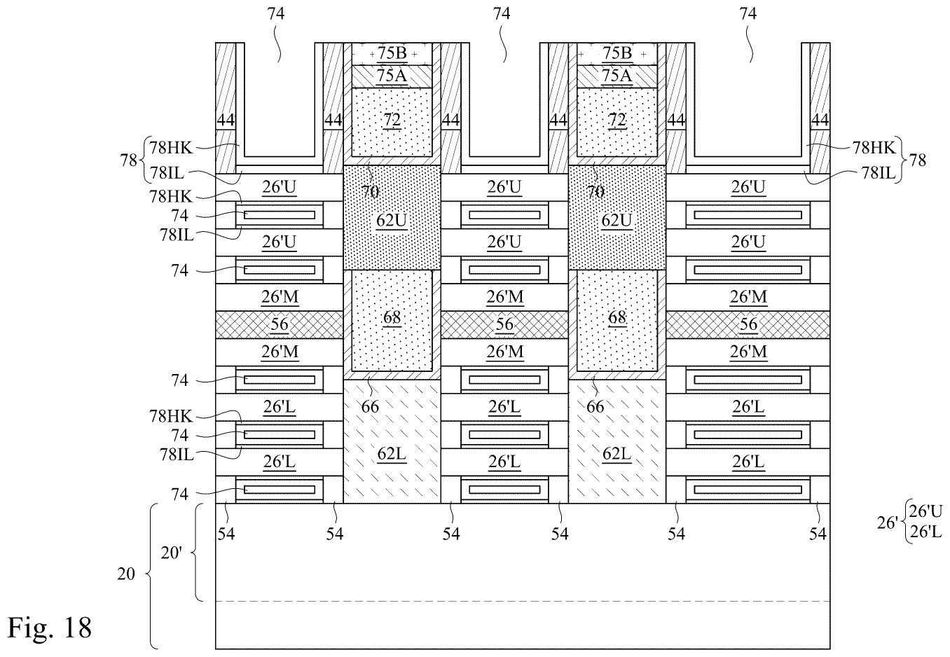

Next, dipole film 128 is removed through an etching process, and the resulting structure is shown in FIG. 17. The respective process is illustrated as process 234 in the process flow 200 as shown in FIG. 24. The remaining scarified regions 124 (not in the plane as illustrated) and protection layer 122 (also not in the plane as illustrated) are then removed. The remaining portions of filling regions 120 are then removed to regenerated recesses 74 between semiconductor nanostructures 26′L, and the resulting structure is shown in FIG. 18. The respective process is also illustrated as process 234 in the process flow 200 as shown in FIG. 24.

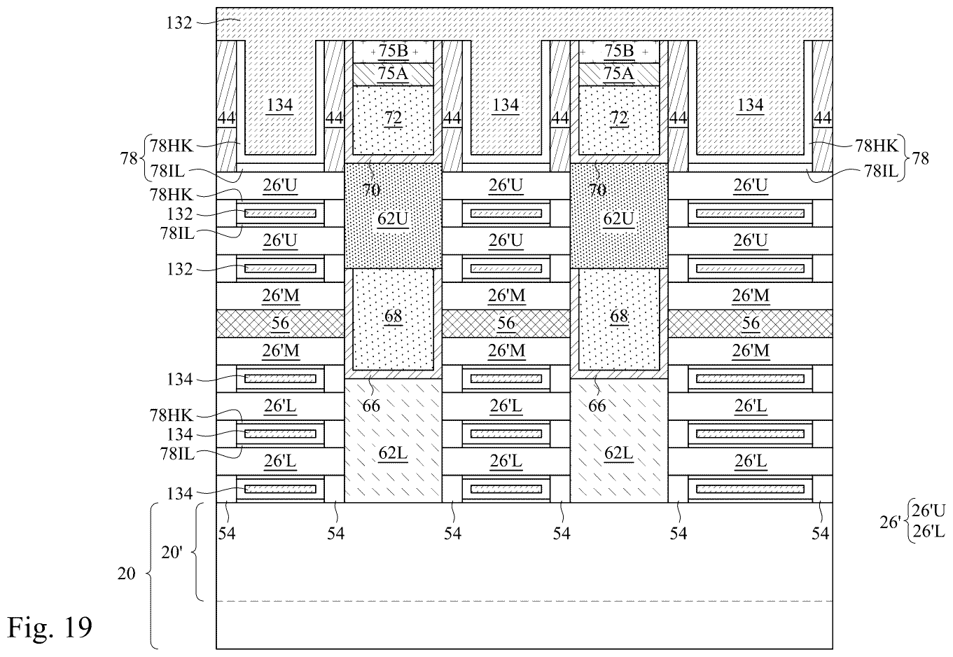

FIG. 19 illustrates the formation of (conductive) gate electrode materials 132, which may include work function layers, and may further include capping layers and filling-metals such as tungsten, cobalt, or the like. The respective process is illustrated as process 236 in the process flow 200 as shown in FIG. 24. In accordance with some embodiments, the gate electrode materials 132 are suitable for the lower FETs. For example, when the lower FETs are PFETs, the gate electrode materials 132 may comprise a work function layer with a (p-type) high work function, which work function material may comprise, for example, TiN.

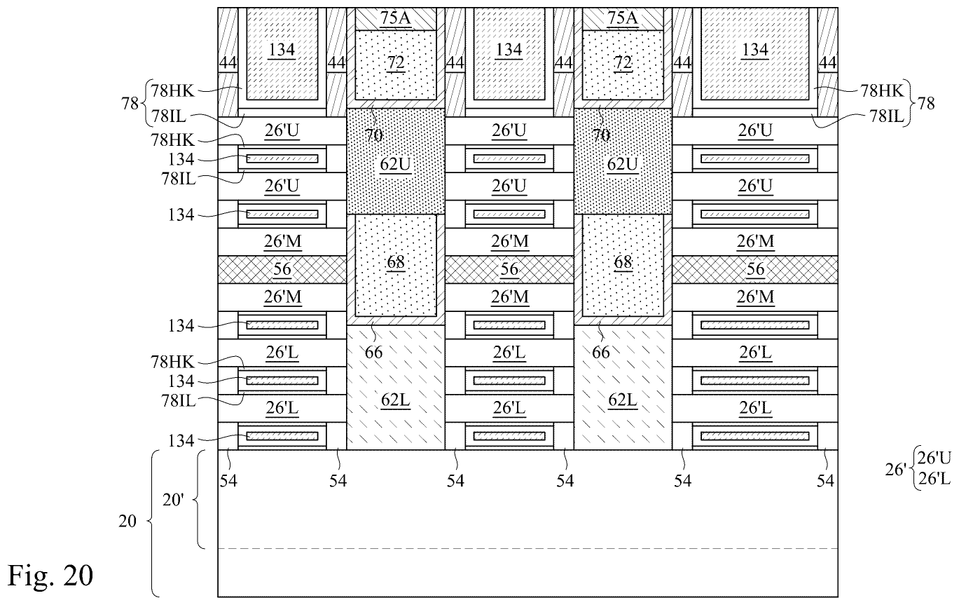

FIG. 20 illustrates the planarization process (such as a CMP process or a mechanical polish process) to remove recess portions of the gate electrode materials 132, forming gate electrodes 134. Gate electrodes 134 include the portions wrapping around the semiconductor nanostructures 26′L and the portions wrapping around the semiconductor nanostructures 26′U. Gate electrodes 134 further include the portions over the top one of the semiconductor nanostructures 26′U. In accordance with some embodiments, in the planarization process, hard masks 75B are removed, and the planarization process stops on the hard masks 75A, which act as the CMP stop layer.

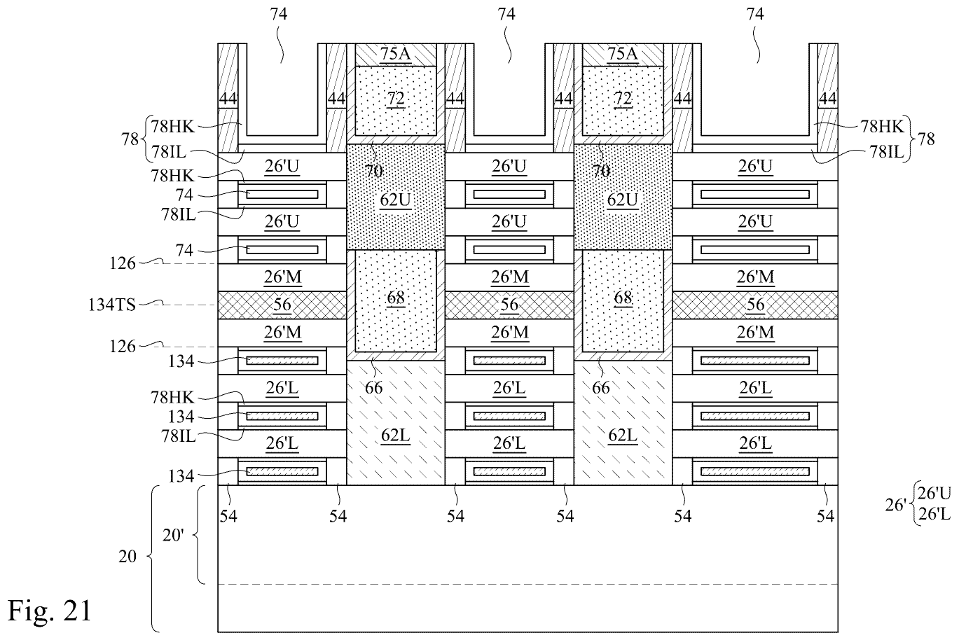

FIG. 21 illustrates the recessing through an etch back (recessing) process to etch back gate electrodes 134. The respective process is illustrated as process 238 in the process flow 200 as shown in FIG. 24. The top surface of the remaining portions of the gate electrodes 134 may also be at any level between dashed lines 126, wherein the top surfaces are in the vertical cross-sections different from the cross-section as shown in FIG. 21. An example top surface of the gate electrodes 134 is shown as top surface 134TS. The remaining portions of the recessed gate electrodes 134 form the gate electrodes of the lower FETs. Recesses 74 are thus regenerated between semiconductor nanostructures 26′U. In the etch back process, hard masks 75A act as an etch stop layer, and protects the underlying ILD 72.

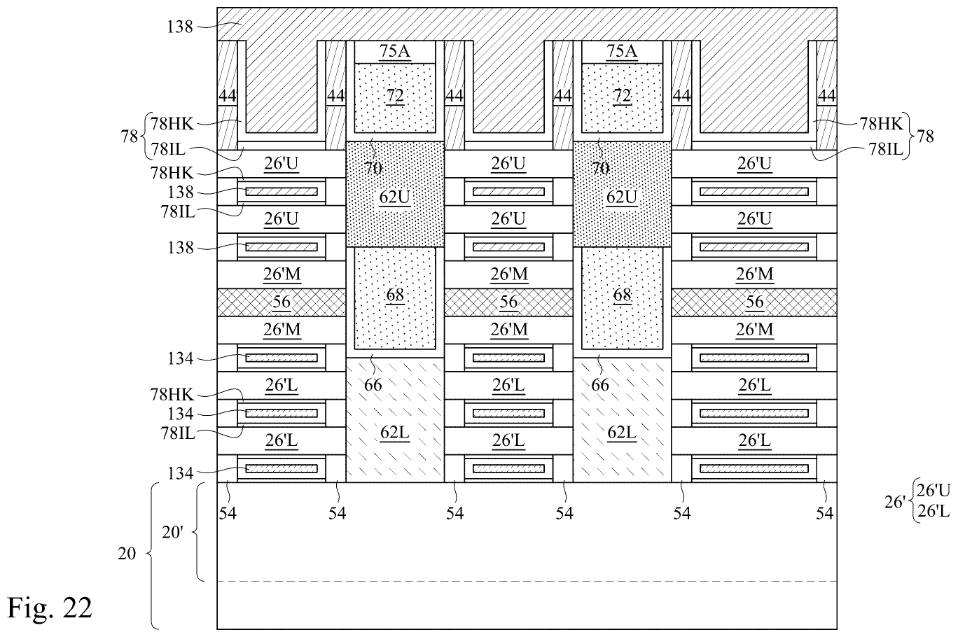

FIG. 22 illustrates the formation of (conductive) gate electrode materials 138, which may include adhesion layers (such as TiN), work function layers (such as aluminum-containing nitride layers). The gate electrode materials 138 may further include capping layers (such as TiN), and filling-metals such as tungsten, cobalt, or the like. In accordance with some embodiments, the gate electrode materials 138 are suitable for the upper FETs. For example, when the upper FETs are NFETs, the electrode materials 138 may comprise a work function layer having a (n-type) low work function, which work function layer may include TiAlN, TiAl, or the like.

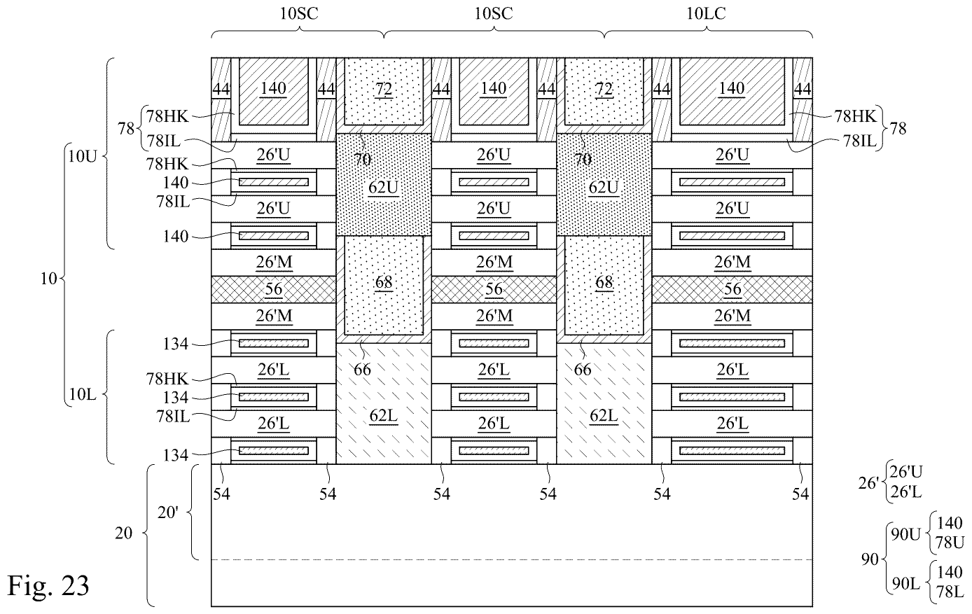

FIG. 23 illustrates the planarization process (such as a CMP process or a mechanical polish process) to remove recess portions of the electrode materials 138, forming upper gate electrodes 140. The respective process is illustrated as process 240 in the process flow 200 as shown in FIG. 24. Upper gate electrodes 140 include the portions wrapping around the semiconductor nanostructures 26′U. In accordance with some embodiments, in the planarization process, hard masks 75A are removed, exposing the underlying ILD 72. In accordance with alternative embodiments, the planarization process is stopped with hard masks 75A acting as a CMP stop layer. Hard masks 75A may be removed in subsequent processes, or remain unremoved.

In FIG. 23, gate dielectrics 78 and lower gate electrodes 134 are collectively referred to as lower gate stacks 90L. The lower gate stacks 90L and lower source/drain regions 62L are parts of the lower FETs 10L. Gate dielectrics 78 and upper gate electrodes 140 are collectively referred to as upper gate stacks 90U. The upper gate stacks 90U and upper source/drain regions 62U are parts of the upper FETs 10U. Lower FETs 10L and the respective upper FETs 10U collectively form short-channel CFETs 10SC and long-channel CFET 10LC.

The embodiments of the present disclosure have some advantageous features. By forming a dual-layer hard mask, the two layers of the dual-layer hard mask may have different etching/CMP property, and thus have lower CMP rate and etching rate in corresponding processes. For example, in the CMP and the etch back of the sacrificial regions, the upper hard masks may have a lower CMP rate and etching rate than the lower hard masks, and thus may function as an effective CMP stop layer and an effective etch stop layer. The lower hard masks, on the other hand, may act as an effective etch stop layer in the selective formation of the lower gate electrodes for the lower FETs.

In accordance with some embodiments of the present disclosure, a method comprises forming a lower source/drain region; forming a upper source/drain region over the lower source/drain region; forming a first contact etch stop layer over the upper source/drain region; forming a first inter-layer dielectric over the first contact etch stop layer; recessing the first inter-layer dielectric to form a first recess; forming a first hard mask in the first recess; forming a second hard mask in the first recess and over the first hard mask; removing a dummy gate stack aside of the second hard mask to form a second recess; depositing a sacrificial material into the second recess; and performing a first chemical mechanical polish (CMP) process on the sacrificial material, wherein a remaining portion of the sacrificial material is left in the second recess to form a sacrificial region, and wherein in the CMP process, the second hard mask acts as a first CMP stop layer.

In an embodiment, the first hard mask comprises silicon nitride, and the second hard mask comprises a silicon-and-carbon-containing dielectric material. In an embodiment, the forming the first hard mask comprises an anisotropic deposition process. In an embodiment, the forming the second hard mask comprises a conformal deposition process. In an embodiment, the method further comprises, after the first CMP process, etching the sacrificial region, wherein when the sacrificial region is etched, the second hard mask acts as an etch stop layer. In an embodiment, in the first CMP process, a slurry is used, and wherein the first hard mask is configured to have a greater CMP rate in response to the slurry than the second hard mask.

In an embodiment, the method further comprises, at a time after the first CMP process, depositing a first conductive material into the second recess; and performing a second CMP process to planarize the first conductive material and to form a first gate electrode, wherein the first hard mask acts a second CMP stop layer, and the second hard mask is removed by the second CMP process. In an embodiment, the method further comprises an additional etching process to recess the first gate electrode, wherein the first hard mask is used as an additional etch stop layer.

In an embodiment, the method further comprises, after the first gate electrode is recessed, depositing a second conductive material into the second recess; and performing a third CMP process to planarize the second conductive material and to form a second gate electrode, wherein the first hard mask is removed by the third CMP process. In an embodiment, the first hard mask and the second hard mask are in contact with sidewalls of the first contact etch stop layer to form interfaces. In an embodiment, the method further comprises forming a second contact etch stop layer over the lower source/drain region; and forming a second inter-layer dielectric over the second contact etch stop layer, wherein the upper source/drain region is formed over the second inter-layer dielectric.

In accordance with some embodiments of the present disclosure, a method comprises recessing an inter-layer dielectric to form a first recess; forming a first hard mask and a second hard mask in the recess, wherein the second hard mask is over the first hard mask, and the first hard mask and the second material comprise different materials; depositing a first material; polishing the first material using the second hard mask as a first polish stop layer; depositing a second material; and polishing the second material using the first hard mask as a second polish stop layer.

In an embodiment, the method further comprises recessing the first material through a first etching process, wherein the second hard mask is further used as a first etch stop layer. In an embodiment, after the first material is recessed, a gate dielectric on an upper semiconductor nanostructure that is aside of the second hard mask is exposed, and the method further comprises depositing a dipole film on the gate dielectric; performing an annealing process on the dipole film; and removing the dipole film.

In an embodiment, the method further comprises recessing the second material through a second etching process, wherein the first hard mask is used as a second etch stop layer. In an embodiment, the method further comprises, at a time after the first material is polished and before the second material is deposited, removing the second hard mask. In an embodiment, the second hard mask is removed through an additional polishing process.

In accordance with some embodiments of the present disclosure, a method comprises forming a lower semiconductor nanostructure and an upper semiconductor nanostructure overlapping the lower semiconductor nanostructure; forming a lower source/drain region aside of the lower semiconductor nanostructure; forming an upper source/drain region aside of the upper semiconductor nanostructure; forming an inter-layer dielectric over the upper source/drain region; forming a dual-layer hard mask comprising a first hard mask and a second hard mask, wherein the dual-layer hard mask is over the inter-layer dielectric; forming a sacrificial material overlapping the upper semiconductor nanostructure; and reducing a height of the sacrificial material, wherein in the reducing, the dual-layer hard mask is used as a stop layer.

In an embodiment, the reducing comprises a polishing process, and wherein the second hard mask is used as a polish stop layer. In an embodiment, the reducing comprises an etching process, wherein the second hard mask is used as an etch stop layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a lower source/drain region;
forming a upper source/drain region over the lower source/drain region;
forming a first contact etch stop layer over the upper source/drain region;
forming a first inter-layer dielectric over the first contact etch stop layer;
recessing the first inter-layer dielectric to form a first recess;
forming a first hard mask in the first recess;
forming a second hard mask in the first recess and over the first hard mask;
removing a dummy gate stack aside of the second hard mask to form a second recess;
depositing a sacrificial material into the second recess; and
performing a first chemical mechanical polish (CMP) process on the sacrificial material, wherein a remaining portion of the sacrificial material is left in the second recess to form a sacrificial region, and wherein in the CMP process, the second hard mask acts as a first CMP stop layer.

2. The method of claim 1, wherein the first hard mask comprises silicon nitride, and the second hard mask comprises a silicon-and-carbon-containing dielectric material.

3. The method of claim 1, wherein the forming the first hard mask comprises an anisotropic deposition process.

4. The method of claim 3, wherein the forming the second hard mask comprises a conformal deposition process.

5. The method of claim 1 further comprising, after the first CMP process, etching the sacrificial region, wherein when the sacrificial region is etched, the second hard mask acts as an etch stop layer.

6. The method of claim 1, wherein in the first CMP process, a slurry is used, and wherein the first hard mask is configured to have a greater CMP rate in response to the slurry than the second hard mask.

7. The method of claim 1 further comprising:
at a time after the first CMP process, depositing a first conductive material into the second recess; and
performing a second CMP process to planarize the first conductive material and to form a first gate electrode, wherein the first hard mask acts a second CMP stop layer, and the second hard mask is removed by the second CMP process.

8. The method of claim 7 further comprising an additional etching process to recess the first gate electrode, wherein the first hard mask is used as an additional etch stop layer.

9. The method of claim 8 further comprising:
after the first gate electrode is recessed, depositing a second conductive material into the second recess; and
performing a third CMP process to planarize the second conductive material and to form a second gate electrode, wherein the first hard mask is removed by the third CMP process.

10. The method of claim 1, wherein the first hard mask and the second hard mask are in contact with sidewalls of the first contact etch stop layer to form interfaces.

11. The method of claim 1 further comprising:
forming a second contact etch stop layer over the lower source/drain region; and
forming a second inter-layer dielectric over the second contact etch stop layer, wherein the upper source/drain region is formed over the second inter-layer dielectric.

12. A method comprising:
recessing an inter-layer dielectric to form a first recess;
forming a first hard mask and a second hard mask in the recess, wherein the second hard mask is over the first hard mask, and the first hard mask and the second hard mask comprise different materials;
depositing a first material;
polishing the first material using the second hard mask as a first polish stop layer;
depositing a second material; and
polishing the second material using the first hard mask as a second polish stop layer.

13. The method of claim 12 further comprising:
recessing the first material through a first etching process, wherein the second hard mask is further used as a first etch stop layer.

14. The method of claim 13, wherein after the first material is recessed, a gate dielectric on an upper semiconductor nanostructure that is aside of the second hard mask is exposed, and the method further comprises:
depositing a dipole film on the gate dielectric;
performing an annealing process on the dipole film; and
removing the dipole film.

15. The method of claim 12 further comprising:
recessing the second material through a second etching process, wherein the first hard mask is used as a second etch stop layer.

16. The method of claim 12 further comprising, at a time after the first material is polished and before the second material is deposited, removing the second hard mask.

17. The method of claim 16, wherein the second hard mask is removed through an additional polishing process.

18. A method comprising:
forming a lower semiconductor nanostructure and an upper semiconductor nanostructure overlapping the lower semiconductor nanostructure;
forming a lower source/drain region aside of the lower semiconductor nanostructure;
forming an upper source/drain region aside of the upper semiconductor nanostructure;
forming an inter-layer dielectric over the upper source/drain region;
forming a dual-layer hard mask comprising a first hard mask and a second hard mask, wherein the dual-layer hard mask is over the inter-layer dielectric;
forming a sacrificial material overlapping the upper semiconductor nanostructure; and
reducing a height of the sacrificial material, wherein in the reducing, the dual-layer hard mask is used as a stop layer.

19. The method of claim 18, wherein the reducing comprises a polishing process, and wherein the second hard mask is used as a polish stop layer.

20. The method of claim 18, wherein the reducing comprises an etching process, wherein the second hard mask is used as an etch stop layer.
